(19) United States
(12) Patent Application Publication
(10) Pub. No.: US 2026/0048419 A1
(43) Pub. Date: Feb. 19, 2026

(54) CHEMICAL MECHANICAL POLISHING SYSTEM CLEANING MODULE

(71) Applicant: Applied Materials, Inc., Santa Clara, CA (US)

(72) Inventors: Ekaterina MIKHAYLICHENKO, Santa Clara, CA (US); Gary Ka Ho LAM, Santa Clara, CA (US); Brian J. BROWN, Palo Alto, CA (US); Yutao MA, Fremont, CA (US)

(21) Appl. No.: 18/802,665

(22) Filed: Aug. 13, 2024

(51) Int. Cl. B08B 1/12; A46B 13/00; A46B 13/02; B08B 1/20; B08B 1/34; B08B 3/02; H01L 21/67

(52) U.S. Cl. CPC B08B 1/12; A46B 13/001; A46B 13/02; B08B 1/20; B08B 1/34; B08B 3/022; A46B 2200/3073; H01L 21/67046

(57) ABSTRACT

A brush cleaning system for cleaning a substrate includes a tank, and a first cylindrical roller, a second cylindrical roller, and a third cylindrical roller disposed in the tank. The brush cleaning system also includes a first cleaning position defined between the first cylindrical roller and the second cylindrical roller, and a second cleaning position defined between the second cylindrical roller and the third cylindrical roller. When the substrate is disposed in the first cleaning position, the first cylindrical roller is configured to clean a first side of the substrate and the second cylindrical roller is configured to clean a second side of the substrate. When the substrate is disposed in the second cleaning position, the second cylindrical roller is configured to clean the second side of the substrate and the third cylindrical roller is configured to clean a first side of the substrate.

### BACKGROUND

### Field

Embodiments of the present invention generally relate to electronic device manufacturing, and in particular, to chemical mechanical polishing (CMP) systems and methods used in a semiconductor device manufacturing processes.

### Description of the Related Art

During chemical mechanical polishing (CMP) processing, scattered particles, such as Cu, Ta, W, TaN, or Ti, may accumulate on both the front surface and back surface of a substrate. To properly remove the scattered particles, most post-CMP cleaning processes include physical cleaning as one of cleaning steps. Typically, the physical cleaning methods largely consist of physically removing excess metals using scrubbing brushes.

CMP systems may include a post-CMP cleaning station for cleaning the substrate after CMP processing. The cleaning station may use scrubbing brushes to remove particles by directly contacting the brush with the substrate surface. Typical cleaning stations consist of one brush on either side of the substrate surface. The brushes are spaced apart when the substrate is received or removed from the scrubbing assembly. The brushes are brought into contact with the substrate during cleaning.

Often times, the substrate may undergo multiple cleanings. In some examples, the CMP system includes multiple cleaning stations to perform multiple cleanings of the substrate. However, the use of multiple cleaning stations may increase processing time and manufacturing costs.

There is, therefore, a need for a brush cleaning unit that can increase throughput and/or reduce manufacturing costs.

### SUMMARY

In some embodiments, a brush cleaning system for cleaning a substrate includes a tank, and a first cylindrical roller, a second cylindrical roller, and a third cylindrical roller disposed in the tank. The brush cleaning system also includes a first cleaning position defined between the first cylindrical roller and the second cylindrical roller, and a second cleaning position defined between the second cylindrical roller and the third cylindrical roller. When the substrate is disposed in the first cleaning position, the first cylindrical roller is configured to clean a first side of the substrate and the second cylindrical roller is configured to clean a second side of the substrate. When the substrate is disposed in the second cleaning position, the second cylindrical roller is configured to clean the second side of the substrate and the third cylindrical roller is configured to clean a first side of the substrate.

In some embodiments, a method of cleaning a substrate includes positioning the substrate at a first cleaning position between a first cleaning roller and a second cleaning roller in a brush cleaner. A first side of the substrate is cleaned using the first cleaning roller, and a second side of the substrate is cleaned using the second cleaning roller. Then the substrate is positioned at a second cleaning position between the second cleaning roller and a third cleaning roller in the brush cleaning. The first side of the substrate is cleaned using the third cleaning roller, and the second side of the substrate is cleaned using the second cleaning roller.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the present disclosure and are therefore not to be considered limiting of its scope, as the present disclosure may admit to other equally effective embodiments.

FIG. 1 is a schematic view of a chemical mechanical polishing (CMP) system, according to certain embodiments.

FIG. 2A is an isometric view of a contact cleaning unit which may be utilized in the CMP system of FIG. 1, according to certain embodiments.

FIG. 2B is a top view of a brush cleaner in FIG. 2A, according to certain embodiments.

FIG. 2C is an isometric view of the brush cleaner of FIG. 2B, according to certain embodiments.

FIG. 3A is a top view of another embodiment of a brush cleaner, which may be utilized in the CMP system of FIG. 1, according to certain embodiments.

FIG. 3B is a perspective view of the brush cleaner of FIG. 3A toward an end of the cylindrical rollers.

FIGS. 4A-4B illustrate sequential operation of a method of cleaning a substrate, according to some embodiments.

FIG. 5 illustrates a flow diagram of a method of cleaning a substrate, according to some embodiments.

FIGS. 6A-6B illustrate schematic top views of a sequential operation of a method of cleaning a substrate, according to some embodiments.

FIG. 7 illustrates a schematic view of an arrangement of brush cleaners which may be utilized in the CMP system of FIG. 1, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein generally relate to chemical mechanical polishing (CMP) systems, and in particular, to cleaning systems used with CMP systems and methods related thereto.

In one embodiment, a brush cleaning system for cleaning a substrate includes a three cylindrical roller configuration to advantageously perform multiple cleanings in the same brush cleaner. The brush cleaning system includes a first cleaning position defined between a first cylindrical roller and a second cylindrical roller, and a second cleaning position defined between the second cylindrical roller and a third cylindrical roller. When the substrate is disposed in the first cleaning position, the first cylindrical roller is configured to clean a first side of the substrate and the second cylindrical roller is configured to clean a second side of the substrate. When the substrate is disposed in the second cleaning position, the second cylindrical roller is configured to clean the second side of the substrate and the third cylindrical roller is configured to clean the first side of the substrate.

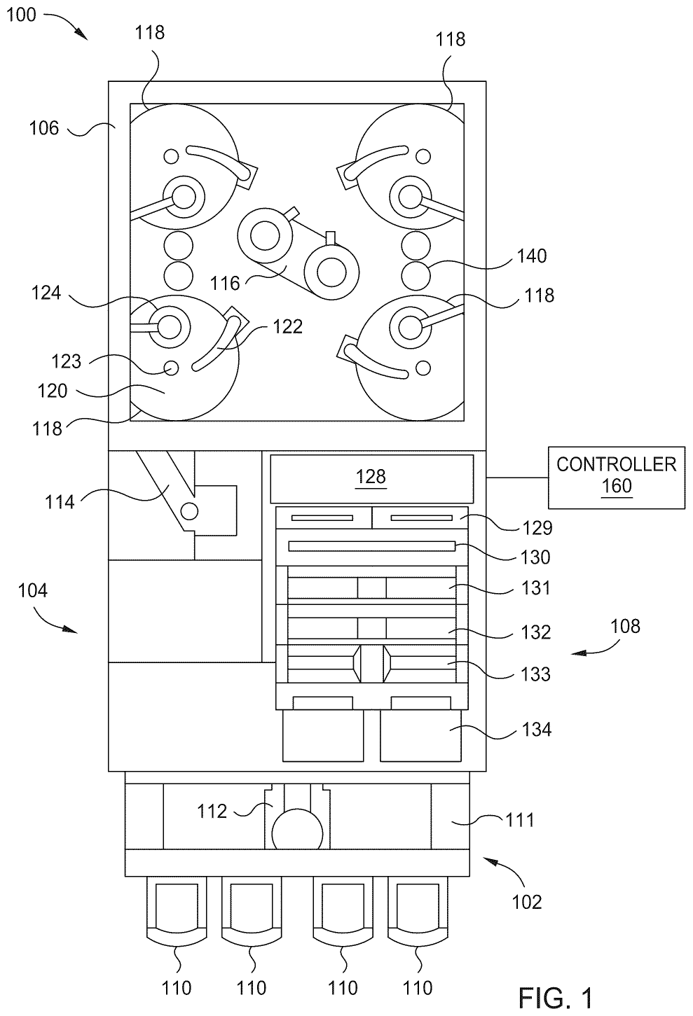

FIG. 1 illustrates a schematic top view of a chemical mechanical polishing (CMP) system 100. The CMP system 100 generally includes a factory interface module 102, an input module 104, a polishing module 106, and a cleaning module 108. These four major components are generally disposed within the CMP system 100.

The factory interface module 102 includes a support to hold a plurality of cassettes 110, a housing 111 that encloses a chamber, and one or more interface robots 112. The interface robot 112 generally provides the range of motion required to transfer substrates between the cassettes 110 and one or more of the other modules of the CMP system 100.

Unprocessed substrates are generally transferred from the cassettes 110 to the input module 104 by the interface robot 112. The input module 104 generally facilitates transfer of a substrate between the interface robot 112 and a transfer robot 114. The transfer robot 114 transfers the substrate between the input module 104 and the polishing module 106.

The polishing module 106 generally comprises a transfer station 116, one or more polishing stations 118, and one or more non-contact cleaning units 140. The transfer station 116 is disposed within the polishing module 106 and is configured to accept the substrate from the transfer robot 114. The transfer station 116 transfers the substrate to at least one carrier head 124 of a polishing station 118 that retains the substrate during polishing.

The polishing stations 118 each includes a rotatable disk-shaped platen on which a polishing pad 120 is situated. The platen is operable to rotate about an axis. The polishing pad 120 can be a two-layer polishing pad with an outer polishing layer and a softer backing layer. The polishing stations 118 each further includes a dispensing arm 122, to dispense a polishing liquid, e.g., an abrasive slurry, onto the polishing pad 120. In the abrasive slurry, the abrasive particles can be silicon oxide, but some polishing processes use cerium oxide abrasive particles. Each polishing station 118 can also include a conditioner head 123 to maintain the polishing pad 120 at a consistent surface roughness.

The polishing stations 118 each includes at least one carrier head 124. The at least one carrier head 124 is operable to hold a substrate against the polishing pad 120 during a polishing operation. Following the polishing operation performed on a substrate, the at least one carrier head 124 transfers the substrate back to the transfer station 116.

The transfer robot 114 then removes the substrate from the polishing module 106 through an opening connecting the polishing module 106 with the remainder of the CMP system 100. The transfer robot 114 removes the substrate in a horizontal orientation from the polishing module 106 and transfers the substrate to the cleaning module 108.

The non-contact cleaning unit 140 may employ methods like megasonic cleaning or spray cleaning to eliminate particles and contaminants from the substrate surface. For example, the non-contact cleaning unit 140 may include megasonic cleaning, which utilizes high-frequency sound waves to create cavitation bubbles in the cleaning solution. The implosion of these bubbles generates shock waves that dislodge particles and contaminants from the substrate surface. Alternatively, the non-contact cleaning unit 140 may include spray cleaning, where high-pressure jets of cleaning solution are used to dislodge particles and contaminants. The non-contact cleaning unit 140 may be a single-arm spray cleaning module employing a single spray arm moving back and forth across the substrate or a dual-arm spray cleaning module with two spray arms moving in opposite directions. Further, the non-contact cleaning unit 140 may be a rotating spray cleaning module that features a rotating spray head above the substrate, spraying cleaning solution from all angles. Additionally, the non-contact cleaning unit 140 may be an inline spray cleaning module integrated into the CMP process line, transporting the substrate on a conveyor belt and spraying it from multiple angles. Conversely, an off-line spray cleaning module operates independently, cleaning substrates outside the CMP process line, which may be loaded manually or with the transfer robot 114.

The cleaning module 108 generally includes one or more cleaning devices that can operate independently or in concert. For example, the cleaning module 108 can include, from top to bottom in FIG. 1, a resist removal module 128, an input module 129, one or more brush or buffing pad module 131, 132, a megasonic cleaner 133, and a drying module 134. Other possible cleaning devices include chemical spin cleaners and jet spray cleaners (not shown). A transport system, e.g., an overhead conveyor 130 that supports robot arms, can walk or run the substrate from cleaning device to cleaning device. In one example, after cleaning in the brush or budding pad module 131, 132, the conveyor 130 can transfer the substrate to the megasonic cleaner 133 in which high frequency vibrations produce controlled cavitation in a cleaning liquid to clean the substrate. Alternatively, the megasonic cleaner 133 can be positioned before the brush or buffing pad module 131, 132. A final rinse can be performed in a rinsing module before being transferred to the drying module 134.

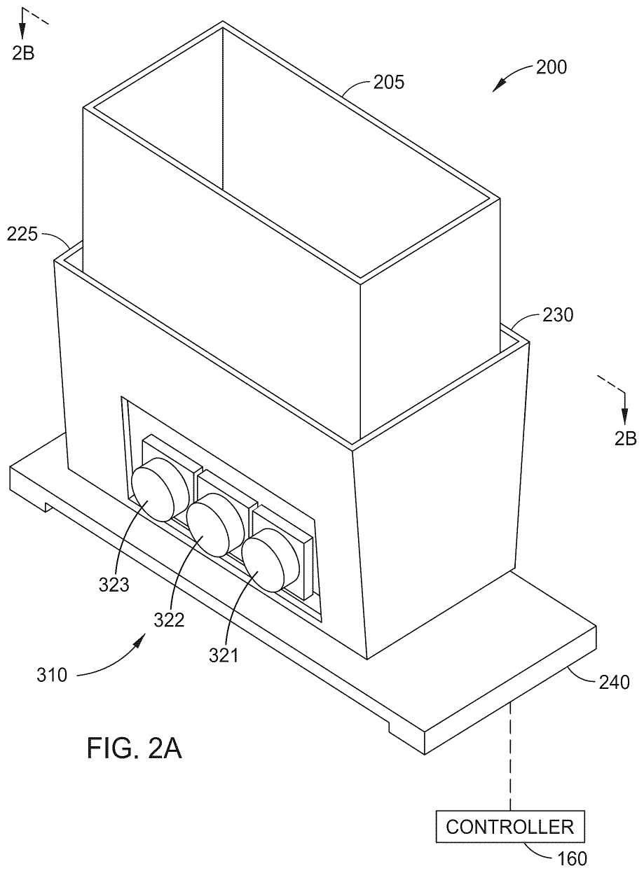

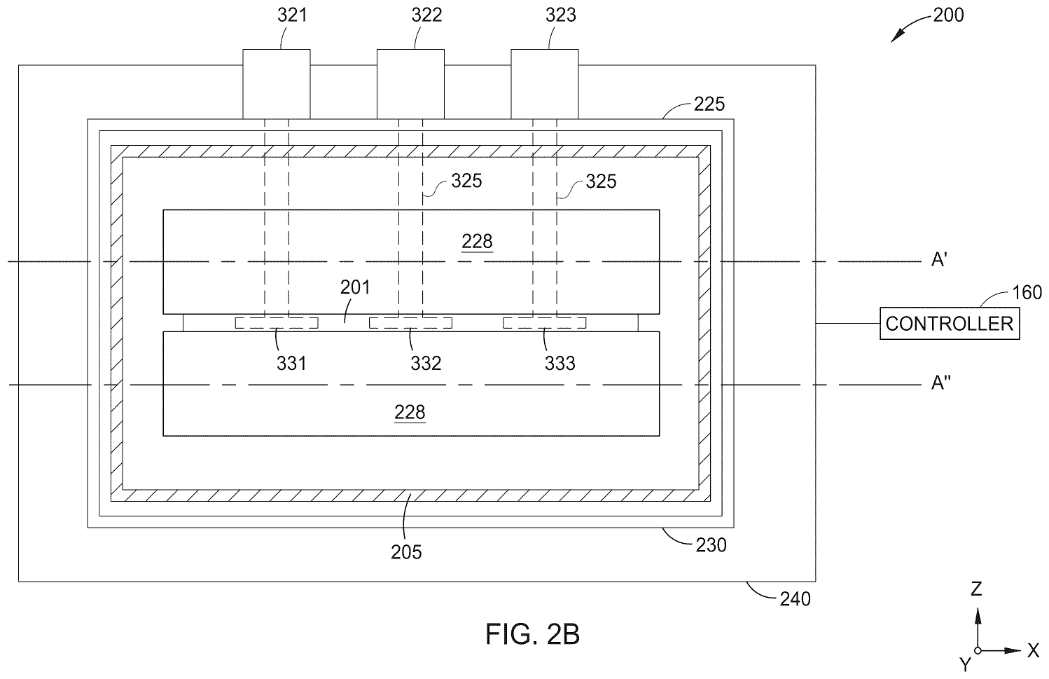

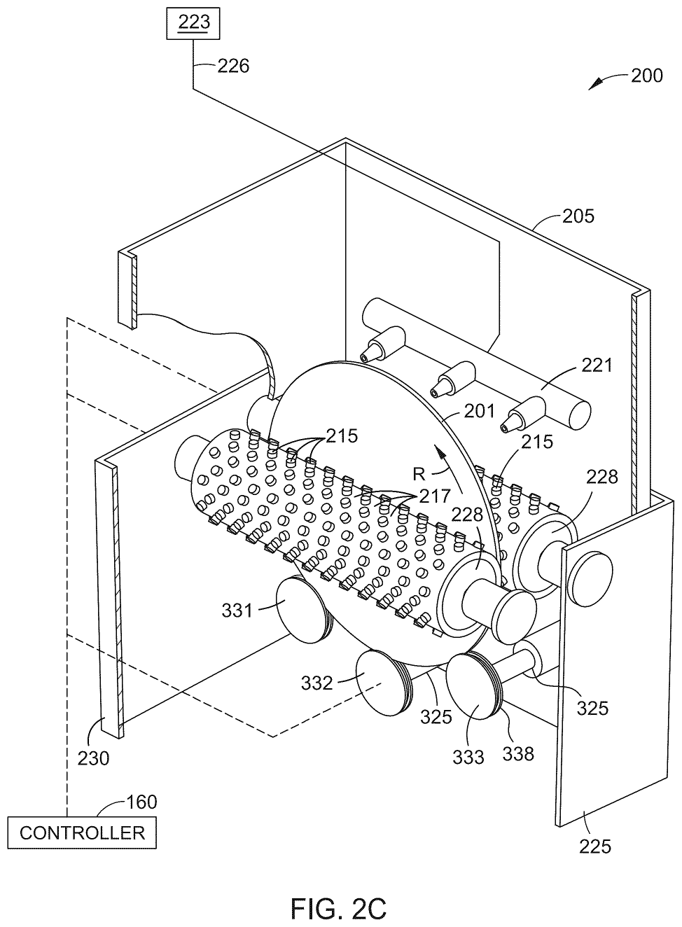

The one or more brush or buffing pad modules 131, 132, which may be represented by the brush cleaner described further below regarding FIGS. 2A-2C, directly contacts the substrate. In some examples, one or more brush or buffing pad modules 131, 132 may be a brush scrubbing module that uses a rotating brush to scrub the substrate surface. Briefly, the one or more brush or buffing pad module 131, 132 are devices in which the substrate can be placed and the surfaces of the substrate are contacted with rotating brushes or spinning buffing pads to remove any remaining particulates. In some embodiments, a brush moves back and forth across the substrate, applying cleaning solution during the scrubbing process. The rotating brush uses friction between the brush bristles and the substrate surface, as well as centrifugal force generated by the rotating brush to dislodge particles and contaminants from the substrate surface. The cleaning solution concurrently dissolves and weakens the bonds between particles and the substrate surface. Following dislodgment of contaminants from the substrate surface, the cleaning solution, flowing through the brush bristles, flushes the contaminants from the substrate surface.

The CMP system 100 includes a controller 160, which generally includes one or more processors, memory, and support circuits. The one or more processors may include a central processing unit (CPU) and may be one of any form of a general purpose processor that can be used in an industrial setting. The memory, or non-transitory computer-readable medium, is accessible by the one or more processors and may be one or more of memory such as random access memory (RAM), read only memory (ROM), floppy disk, hard disk, or any other form of digital storage, local or remote. The support circuits are coupled to the one or more processors and may comprise cache, clock circuits, input/output subsystems, power supplies, and the like. The various methods disclosed herein may generally be implemented under the control of the one or more processors by the one or more processors executing computer instruction code stored in the memory as, for example, a software routine. When the computer instruction code is executed by the one or more processors, the one or more processors controls the CMP system 100 to perform processes in accordance with the various methods disclosed herein.

FIG. 2A is an isometric view of a brush cleaner 200, which may be utilized as one or more brush or buffing pad modules 131, 132 in the CMP system 100 as described above. A lid portion of the brush cleaner 200, which includes a door, has been removed from FIGS. 2A-2C for ease of discussion. FIG. 2B is a top view of the brush cleaner 200 loaded with a substrate 201. FIG. 2C is an isometric view of the interior of the brush cleaner 200 showing cylindrical rollers 228 in a processing position, in which the cylindrical rollers 228 are closed (e.g., pressed) against major surfaces of the substrate 201. The brush cleaner 200 shown in FIGS. 2A-2C can be a scrubber brush box-type vertical cleaner. The example brush cleaner 200 includes a tank 205 that is supported by a first support 225 and a second support 230. The first support 225 and the second support 230 are movably coupled to the base 240.

The brush cleaner 200 includes a plurality of scrubbing devices, such as at least a first and second cylindrical rollers 228, located inside the tank 205. In this embodiment, the pair of cylindrical rollers 228 are supported by a pivotal mounting adapted to move the cylindrical rollers 228 into and out of contact with the substrate 201, such as a semiconductor wafer. For example, a first cylindrical roller 228 is mounted to the first support 225, and a second cylindrical roller 228 is mounted to the second support 230. The first and second supports 225, 230 may be moved simultaneously relative to a base 240. Such movement may cause the first and second cylindrical rollers 228 to close against the substrate 201 as shown in FIG. 2C, or to cause the first and second cylindrical rollers 228 to be spaced apart to allow insertion and/or removal of the substrate 201 from the brush cleaner 200.

The first and second cylindrical rollers 228 may be coupled to actuators (e.g., drive motors, not shown) for rotating the cylindrical rollers 228 about axes A′ and A″. The cylindrical rollers 228 are coupled to and controlled by the controller 160, which may control the rotational speed or rotational direction of the rollers 228. In some embodiments, the rollers 228 are rotated in opposite directions. In one example, the first roller 228 is rotated in a clockwise direction, and the second roller 228 is rotated in a counterclockwise direction. In some embodiments, each cylindrical roller 228 includes a plurality of raised nodules 215 across its outer surface and a plurality of valleys 217 located among the nodules 215.

The brush cleaner 200 also include a substrate support system 310 adapted to support and rotate a substrate 201. In one embodiment, the substrate support system 310 includes one or more support rollers 331, 332, 333 rotatable by one or more rotation actuators, such as drive motors 321, 322, 323. As shown in FIGS. 2B and 2C, each support roller 331, 332, 333 is disposed at the end of an output shaft 325 of a respective drive motor 321, 322, 323. The support rollers 331, 332, 333 are configured to support the substrate 201 and facilitate rotation of the substrate 201 about an axis that is perpendicular to the horizontal plane (i.e., X-Y plane). In one example, each of the support rollers 331, 332, 333 include a groove 338 adapted to vertically support the substrate 201. Rotation of the support rollers 331, 332, 333 causes rotation of the substrate 201. In some embodiments, the rollers 331, 332, 333 are made from a plastic material or other polymeric material.

During processing in the brush cleaner 200, the cylindrical rollers 228 are brought into contact with the substrate 201 by moving the first and second supports 225, 230, while the cylindrical rollers 228 are rotated by the actuators (not shown). At the same time, the substrate 201 is rotated in the R direction by rotating the support rollers 331, 332, 333, as shown in FIG. 2C. A cleaning fluid, such as deionized water and/or acid or base containing aqueous solution, is applied to the surface of the substrate 201 from a fluid source while the substrate 201 and cylindrical rollers 228 are rotated by the various actuators and motors.

The brush cleaner 200 may further include a plurality of sprayers 221 coupled to a source 223 of cleaning fluid via a supply pipe 226. The sprayers 221 are configured to dispense a high-pressure liquid spray onto the substrate surfaces, aiding in the removal of particles, contaminants, and residues. The sprayers 221 can incorporate various configurations, such as a fluid jet, spray bar with nozzles, shower-style spray manifold, or cryogenic aerosol jet.

In various embodiments of the present disclosure, the cleaning fluid utilized in the brush cleaner may include, but is not limited to deionized (DI) water, diluted citric acid, diluted Quaternary ammonium compound (a mixture of organic solvents, such as glycol ether, tetramethyl ammonium hydroxide, and other additives), diluted ammonium hydroxide (NH₄OH), diluted hydrogen peroxide (H₂O₂), NH₄OH and H₂O₂ mixture (SC1), diluted hydrofluoric acid, sulfuric acid (H2SO4) and hydrogen peroxide (H₂O₂) mixture, Electra clean, or any other liquid solution used for substrate cleaning.

In one or more embodiments, the sprayers 221 may be positioned to spray a cleaning fluid at the surfaces of the substrate 201 or at the one or more cylindrical rollers 228 during a scrubbing process. In one or more embodiments, substrate cleaning fluid and/or brush cleaning fluid may be supplied from an internal region of the cylindrical rollers 228. Fluids provided to the interior of the cylindrical rollers 228 may clean the surface of the substrate 201 or remove debris found on the surface of the rollers 228.

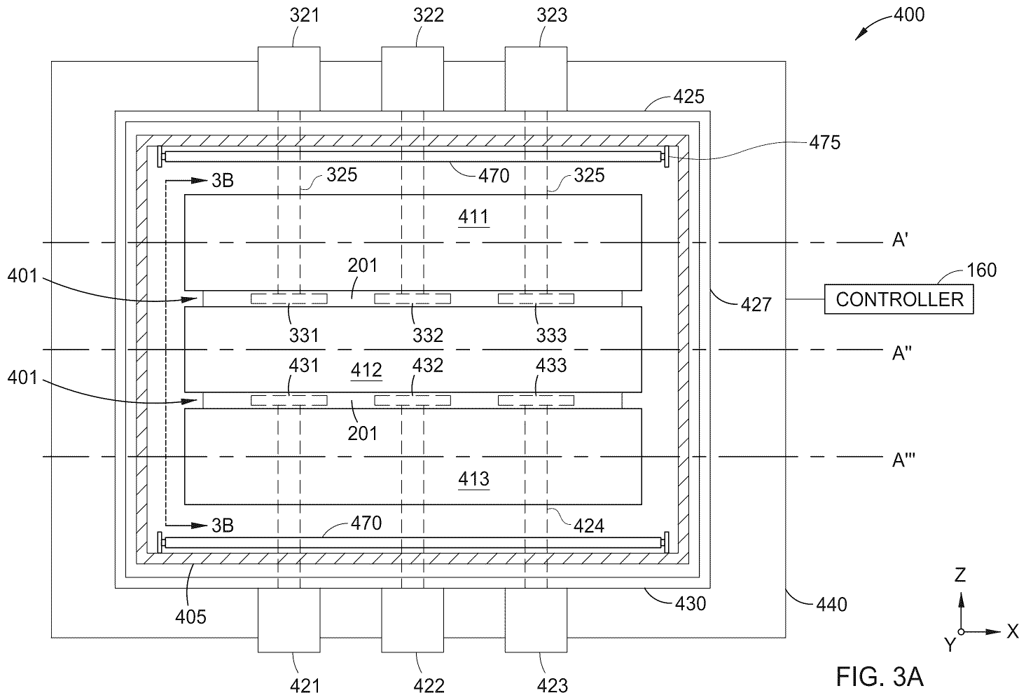

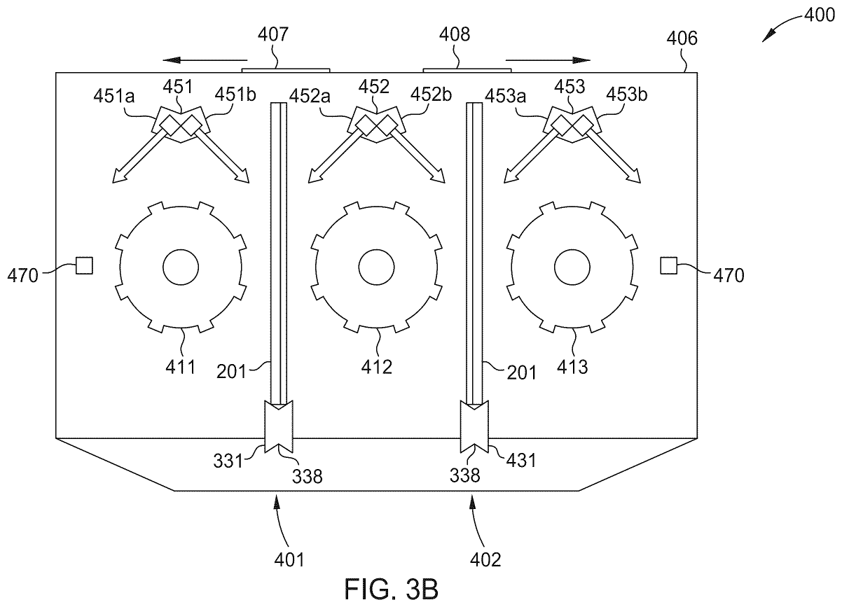

FIGS. 3A and 3B illustrate another embodiment of a brush cleaner 400, which may be utilized as one or more brush or buffing pad modules 131, 132 in the CMP system 100 as described above. FIG. 3A is a schematic top view of the brush cleaner 400. FIG. 3B is a perspective view of the brush cleaner 400 toward an end of cylindrical rollers 411, 412, 413. As shown, the brush cleaner 400 includes three cylindrical rollers 411, 412, 413, which may be the rollers 228 described above with respect to FIGS. 2B-2C. The rollers 228, 411, 412, 413 may also be referred to as cleaning rollers. FIG. 3B also show a lid portion 406 of the brush cleaner 400, which lid portion 406 includes two doors 407, 408. The doors 407, 408 are movable between an open position and a closed position to allow the insertion or removal of the substrate 201. As shown, the brush cleaner 400 is loaded with two substrates 201. One of the substrates 201 is disposed in a first cleaning position 401 located between the first roller 411 and the second roller 412, and the other substrate 201 is disposed in a second cleaning position 402 located between the second roller 412 and the third roller 413. It is contemplated that the brush cleaner 400 may be loaded with only a single substrate 201, such as the first cleaning position 401 or the second cleaning position 402. The brush cleaner 400 shown in FIGS. 3A-3B can be a scrubber brush box-type horizontal cleaner. The example brush cleaner 400 includes a tank 405 that is supported by a first support 425, a second support 427, and a third support 430. The first, second, and third supports 425, 427, 430 are movably coupled to a base 440.

The brush cleaner 400 includes a plurality of scrubbing devices, such as at least a first, second, and third cylindrical rollers 411, 412, 413, located inside the tank 405. In this embodiment, the cylindrical rollers 411, 412, 413 are supported by a pivotal mounting adapted to move the cylindrical rollers 411, 412, 413 into and out of contact with the substrate 201, such as a semiconductor wafer. For example, a first cylindrical roller 411 is mounted to the first support 425, a second cylindrical roller 412 is mounted to the second support 427, and a third cylindrical roller 413 is mounted to the third support 430. The first support 425, second support 427, and third support 430 may be moved independently relative to a base 440. In one example, movement of the first support 425 and the second support 427 may cause the first and second cylindrical rollers 411, 412 to close against the substrate 201 located in the first cleaning position 401, or to cause the first and second cylindrical rollers 411, 412 to be spaced apart to allow insertion and/or removal of the substrate 201 from the brush cleaner 400. Similarly, movement of the second support 427 and the third support 430 may cause the second and third cylindrical rollers 412, 413 to close against the substrate 201 located in the second cleaning position 402, or to cause the second and third cylindrical rollers 412, 413 to be spaced apart to allow insertion and/or removal of the substrate 201 from the brush cleaner 400.

The first, second, and third cylindrical rollers 411, 412, 413 may be coupled to actuators (e.g., drive motors, not shown) for rotating the cylindrical rollers 411, 412, 413 about axes A′, A″, and A′″. The cylindrical rollers 411, 412, 413 are coupled to and controlled by the controller 160, which may control the rotational speed or rotational direction of the rollers 411, 412, 413. In some examples, the first, second, and third cylindrical rollers 411, 412, 413 can be independently rotated in the same or different directions. For example, the first roller 411 is rotated in a clockwise direction, and the second roller 412 is rotated in a counterclockwise direction. In another example, the second roller 412 is rotated in a clockwise direction, and the third roller 413 is rotated in a counterclockwise direction. As discussed above, each cylindrical roller 411, 412, 413 includes a plurality of raised nodules 215 across its outer surface and a plurality of valleys 217 located among the nodules 215.

The brush cleaner 400 also include a substrate support system 410 adapted to support and rotate a substrate 201. In one embodiment, the substrate support system 410 includes one or more support rollers 331, 332, 333 rotatable by one or more rotation actuators, such as drive motors 321, 322, 323. As shown in FIGS. 3A and 3B, each support roller 331, 332, 333 is disposed at the end of an output shaft 325 of a respective drive motor 321, 322, 323. The support rollers 331, 332, 333 are configured to support a substrate 201 disposed in the first cleaning position 401 located between the first and second rollers 411, 412.

The substrate support system 410 also includes one or more support rollers 431, 432, 433 rotatable by one or more rotation actuators, such as drive motors 421, 422, 423. As shown in FIGS. 3A and 3B, each support roller 431, 432, 433 is disposed at the end of an output shaft 424 of a respective drive motor 421, 422, 423. The support rollers 431, 432, 433 are configured to support a substrate 201 disposed in the second cleaning position 402 located between the second and third rollers 412, 413. While two sets of three support rollers 331, 332, 333, 431, 432, 433 are shown, it is contemplated that each set may include one, two, four, or more support rollers. The support rollers 331, 332, 333, 431, 432, 433 are configured to facilitate rotation of the substrate 201 about an axis that is perpendicular to the horizontal plane (i.e., X-Y plane). In one example, each of the support rollers 331, 332, 333, 431, 432, 433 includes a groove 338 adapted to vertically support the substrate 201. Rotation of the support rollers 331, 332, 333, 431, 432, 433 causes rotation of the substrate 201 supported thereon. In some embodiments, the rollers 331, 332, 333, 431, 432, 433 are made from a plastic material or other polymeric material. In another embodiment, the support rollers 431, 432, 433 may be connected to drive motors 321, 322, 323, respectively, such that drive motors 421, 422, 423 are not required. For example, the output shaft 325 of the support roller 331 may be extended and connected to the support roller 431 such that both support rollers 331, 431 may be rotated by drive motor 321.

According to some embodiments, a conditioning device 470 may be provided in the tank 405 for interacting with the first or second cylindrical rollers 411, 413. The conditioning device 470 may be referred to as a “beater bar.” In this example, the conditioning device 470 is mounted on a sidewall of the tank 205 adjacent the first and third cylindrical rollers 411, 413 using one or more support members 475. The conditioning device 470 is positioned to contact the adjacent cylindrical roller 411, 413 when the cylindrical roller 411, 413 is not cleaning the substrate 201. Additionally, the conditioning device 470 is positioned away from the center of the tank 205 to avoid interference with substrate transfer and/or substrate polishing or cleaning processes. In one embodiment, the movement of the first and third supports 425, 430 brings the first and third cylindrical rollers 411, 413, respectively, into contact with a respective conditioning device 470. In this position, the cleaning surface on the cylindrical rollers 411, 413 may be conditioned while the substrate 201 is being cleaned by the other two cylindrical rollers 411, 412, 413. For example, the third cylindrical roller 413 may be conditioned while the first and second cylindrical rollers 411, 412 clean the substrate 201. In some embodiments, the conditioning device 470 may be a brush conditioning bar. The conditioning device 470 such as the brush conditioning bar can be made out of quartz, plastic silicon carbide or other materials having a rough surface.

In one example, during processing in the brush cleaner 400, the first and second cylindrical rollers 411, 412 are brought into contact with the substrate 201 in the first cleaning position 401 while the cylindrical rollers 411, 412 are rotated by the actuators (not shown). At the same time, the substrate 201 is rotated in the R direction by rotating the support rollers 331, 332, 333. A cleaning fluid, such as deionized water and/or acid or base containing aqueous solution, is applied to the surface of the substrate 201 from a fluid source while the substrate 201 and cylindrical rollers 411, 412 are rotated by the various actuators and motors. At the same time, the third cylindrical roller 413 is not in contact with the substrate 201 and may be cleaned by the cleaning fluid while being rotated. Optionally, the third cylindrical roller 413 can be conditioned (e.g., scrubbed) against the adjacent conditioning device 470. Similarly, the second and third cylindrical rollers 412, 413 are brought into contact with the substrate 201 in the second cleaning position 402 while the cylindrical rollers 412, 413 are rotated by the actuators (not shown). At the same time, the substrate 201 is rotated in the R direction by rotating the support rollers 431, 432, 433. A cleaning fluid, such as deionized water and/or acid or base containing aqueous solution, is applied to the surface of the substrate 201 from a fluid source while the substrate 201 and cylindrical rollers 412, 413 are rotated by the various actuators and motors. At the same time, the first cylindrical roller 411 is not in contact with the substrate 201 and may be cleaned by the cleaning fluid and/or the conditioning device 470 while being rotated.

The brush cleaner 400 may further include a plurality of sprayers 451, 452, 453 coupled to a source 223 of cleaning fluid via one or more supply pipes 226. The sprayers 451, 452, 453 are configured to dispense a high-pressure liquid spray onto the substrate surfaces, aiding in the removal of particles, contaminants, and residues. The sprayers 451, 452, 453 can incorporate various configurations, such as a fluid jet, spray bar with nozzles, shower-style spray manifold, or cryogenic aerosol jet. In some embodiments, each sprayer 451, 452, 453 is positioned above a respective cylindrical roller 411, 412, 413. The sprayers 451, 452, 453 may be positioned to spray a cleaning fluid at the surfaces of the substrate 201 or at the one or more cylindrical rollers 411, 412, 413 during a scrubbing process. Each sprayer 451, 452, 453 may include at least two nozzles 451a,b, 452a,b, 453a,b that are configured to direct cleaning fluid to the left side or right side of the respective cylindrical roller 411, 412, 413. In this example, the second sprayer 452 includes a nozzle 452a directed to the first cleaning position 401 (i.e., left side) and a nozzle 452b directed to the second cleaning position 402 (i.e., right side). The first sprayer 451 includes a left nozzle 451a directed to the first roller 411 to clean the first roller 411 when the first roller 411 is not cleaning a substrate 201 and includes a right nozzle 451b directed to the first cleaning position 401. The third sprayer 453 includes a left nozzle 453a directed to the second cleaning position 402 and a right nozzle 453b directed to the third first roller 413 to clean the third roller 413 when the third roller 413 is not cleaning a substrate 201. In some embodiments, the sprayers 451, 452, 453 may include a single nozzle, which may be fixed or rotatable.

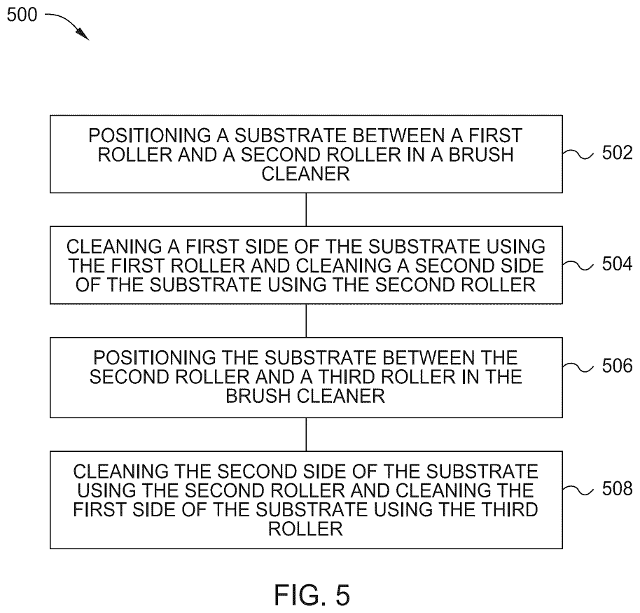

FIG. 5 illustrates a flow diagram of a method 500 of cleaning a substrate, e.g., substrate 201, which may be performed by a controller of a CMP system, e.g., controller 160 of CMP system 100.

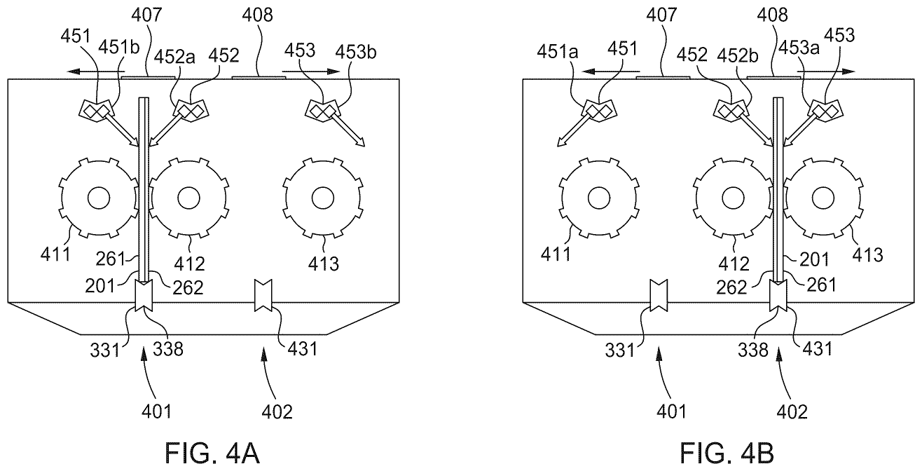

At operation 502, a substrate 201 is placed in a brush cleaner 400, as shown in FIG. 4A. The brush cleaner 400 may be used as a brush or buffing pad module 131, 132 of the CMP system 100. In some embodiments, the substrate 201 is transferred to the brush cleaner 400 after being polished in a polishing station of the polishing stations 118. The substrate 201 may be transferred using the conveyor 130 and may be inserted into the brush cleaner 400 through the first door 407. The substrate 201 is positioned in a first cleaning position 401 between the first cylindrical roller 411 and the second cylindrical roller 412 for cleaning. The substrate 201 is positioned vertically on the support rollers 331, 332, 333. In one example, the first and second cylindrical rollers 411, 412 are pressed against the major surfaces of the substrate 201. In this example, the first cylindrical roller 411 contacts a first side 261 (e.g., front side) of the substrate 201, and the second cylindrical roller 412 contacts a second side 262 (e.g., back side) of the substrate 201.

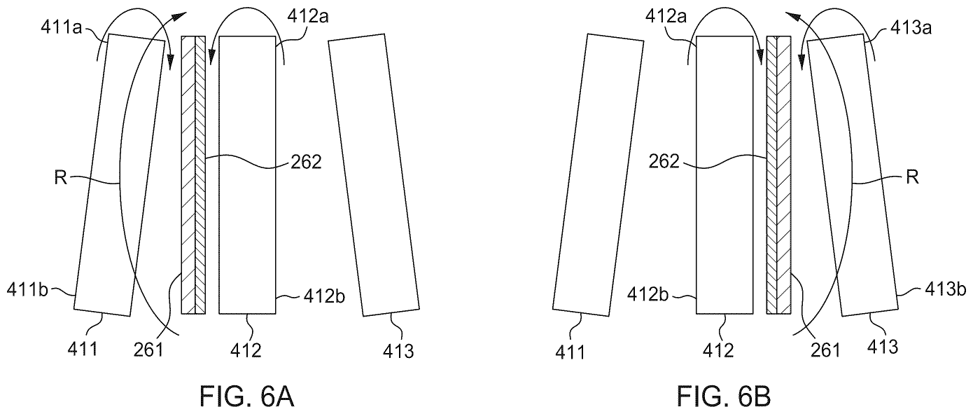

At operation 504, the brush cleaner 400 cleans the substrate 201. At least one of the support rollers 331, 332, 333 is rotated by a drive motor 321, 322, 323 to cause rotation of the substrate 201 in the R direction as shown in FIG. 6A, which is a schematic top view of the cylindrical rollers 411, 412, 413. The cylindrical rollers 411, 412 contacting the substrate 201 are also rotated during cleaning of the substrate 201. In this example, the first cylindrical roller 411 is rotated in the clockwise direction to clean the first side 461, and the second cylindrical roller 412 is rotated in the counterclockwise direction to clean the second side 462 of the substrate 201. In some embodiments, the first cylindrical roller 411 is positioned at an angle from 0° to 15° or from 3° to 15° relative to the substrate 201 such that a front end 411a of the first cylindrical roller 411 is closer to the substrate 201 than the back end 411b. The second cylindrical roller 412 may be positioned in longitudinal alignment with the substrate 201, such as positioned at an angle from 0° to 3° relative to the substrate 201. In some embodiments, second cylindrical roller 412 may be positioned at an angle, such as from 3° to 15°, relative to the substrate 201 such that a front end 412a of the second cylindrical roller 412 is closer to the substrate 201 than the back end 412b. A cleaning fluid is applied to the surfaces of the substrate 201 as the cylindrical rollers 411, 412 are rotated. In one example, the right nozzle 451b of the first sprayer 451 applies cleaning fluid toward the first side 261 of the substrate 201, as shown in FIG. 4A. Also, the left nozzle 452a of the second sprayer 452 applies cleaning fluid toward the second side 262 of the substrate 201. In some examples, the right nozzle 453b of the third sprayer 453 applies cleaning fluid toward the third cylindrical roller 413 to clean the third cylindrical roller 413.

At operation 506, after being cleaned while in the first cleaning position 401, the substrate 201 is moved to the second cleaning position 402 in the brush cleaner 400, as shown in FIGS. 4B and 6B. In this example, the substrate 201 is moved between the two cleaning positions 401, 402 using the conveyor 130. In some embodiments, the first and second cylindrical rollers 411, 412 are moved out of contact with the substrate 201 before the conveyor 130 retrieves the substrate 201. The substrate 201 may be removed via the first door 407 and positioned at the second cleaning position 402 via insertion through the second door 408. In the second cleaning position 402, the substrate 201 is disposed between the second cylindrical roller 412 and the third cylindrical roller 413 for cleaning. The substrate 201 is positioned vertically on the support rollers 431, 432, 433. In this example, the second cylindrical roller 412 is moved into contact with the second side 262 (e.g., back side) of the substrate 201, and the third cylindrical roller 413 is moved into contact with the first side 261 (e.g., front side) of the substrate 201. In this respect, the substrate 201 is rotated about 180 degrees between first cleaning position 401 and the second cleaning position 402 such that the backside 262 of the substrate 201 faces the second cylindrical roller 412 when the substrate 201 is in either the first cleaning position 401 or the second cleaning position 402.

At operation 508, the brush cleaner 400 performs a second cleaning on the substrate 201. At least one of the support rollers 431, 432, 433 is rotated by a rotation actuator, such as drive motors 421, 422, 423 to cause rotation of the substrate 201. The second and third cylindrical rollers 412, 413 contacting the substrate 201 are also rotated during cleaning of the substrate 201, as shown in FIG. 6B. In this example, the second cylindrical roller 412 is rotated in the clockwise direction to clean the second side 462, and the third cylindrical roller 413 is rotated in the counterclockwise direction to clean the first side 461 of the substrate 201. In some embodiments, the third cylindrical roller 413 is positioned at an angle from 0° to 15° or from 3° to 15° relative to the substrate 201 such that a front end 413a of the third cylindrical roller 413 is closer to the substrate 201 than the back end 413b. The second cylindrical roller 412 may be positioned in substantial longitudinal alignment with the substrate 201. In some embodiments, second cylindrical roller 412 may be positioned at a slight angle, such as from 1° to 15°, relative to the substrate 201 such that a front end 412a of the second cylindrical roller 412 is closer to the substrate 201 than the back end 412b. A cleaning fluid is applied to the surfaces of the substrate 201 as the cylindrical rollers 412, 413 are rotated. In one example, the right nozzle 452b of the second sprayer 452 applies cleaning fluid toward the second side 262 of the substrate 201, as shown in FIG. 4B. Also, the left nozzle 453a of the third sprayer 453 applies cleaning fluid toward the first side 261 of the substrate 201. In some examples, the left nozzle 451a of the first sprayer 451 applies cleaning fluid toward the first cylindrical roller 411 to clean the first cylindrical roller 411. In this manner, the brush cleaner 400 advantageously performs multiple cleanings of the substrate 201 using a three cylindrical roller configuration. The second cylindrical roller 412 is beneficially used to clean the backside of the substrate 201 in both the first and second cleaning positions 401, 402. The second cylindrical roller 412 can be advantageously paired with the first cylindrical roller 411 and the third cylindrical roller 413 for both cleanings. Consequently, a brush cleaner 400 is efficiently used to perform multiple cleaning of the substrate to increase throughput and to reduce manufacturing costs of the CMP system.

In some embodiments, after cleaning, the substrate 201 is transferred to a non-contact cleaning unit, such as a megasonic cleaner 133 and/or a drying module 134. The non-contact cleaning unit then cleans the substrate 201 using a non-contact cleaning method, such as megasonic cleaning or spray cleaning. For example, the substrate 201 may undergo spray cleaning where high-pressure jets of cleaning solution are directed toward the substrate 201 to dislodge particles and contaminants. It is contemplated that the substrate 201 may be transferred to a second brush or buffing pad module 131, 132 instead of or in addition to the non-contact cleaning unit. In some embodiments, after cleaning, the substrate is transferred to the factory interface module 102 and cassettes 110.

In some embodiments, after cleaning, the substrate 201 is transferred to a polishing station of the polishing stations 118 for polishing or additional polishing if the substrate 201 was previously polished. After polishing, the substrate 201 is transferred to a non-contact cleaning unit, such as a megasonic cleaner 133 and/or a drying module 134.

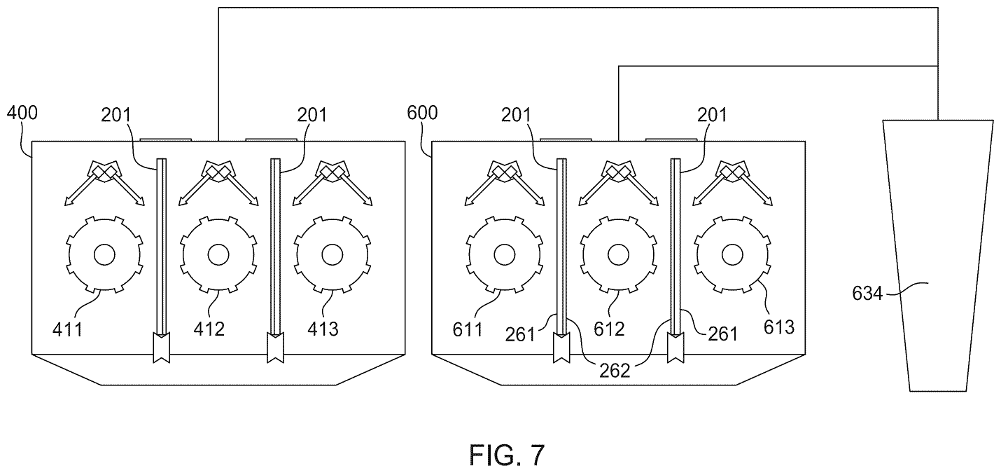

In some embodiments, the CMP system 100 may be equipped with two or more of the brush cleaners 400, 600, as shown in FIG. 7. The second brush cleaner 600 may be similarly configured with a three cylindrical roller configuration, such as cylindrical rollers 611, 612, 613. In this example, the first cylindrical roller 611 cleans the first side 261 (e.g., front side) of the substrate 201, and the second cylindrical roller 612 cleans the second side 262 (e.g., back side) of the substrate 201 when the substrate 201 is in the first cleaning position between the first and second rollers 611, 612. When the substrate 201 is in the second cleaning position between the second and third rollers 612, 613, the second cylindrical roller 612 cleans the second side 262 (e.g., back side) of the substrate 201, and the third cylindrical roller 613 cleans the first side 261 (e.g., front side) of the substrate 201. After cleaning, the substrate 201 from the brush cleaners 400, 600 are transferred to the drying module 634, such as drying module 134. In this respect, a single drying module 634 is efficiently used to dry the substrate 201 from two brush cleaners 400, 600.

When introducing elements of the present disclosure or exemplary aspects or embodiments thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another—even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A brush cleaning system for cleaning a substrate, comprising:
a tank;
a first cylindrical roller, a second cylindrical roller, and a third cylindrical roller disposed in the tank;
a first cleaning position defined between the first cylindrical roller and the second cylindrical roller; and
a second cleaning position defined between the second cylindrical roller and the third cylindrical roller, wherein,
when the substrate is disposed in the first cleaning position, the first cylindrical roller is configured to clean a first side of the substrate and the second cylindrical roller is configured to clean a second side of the substrate, and
when the substrate is disposed in the second cleaning position, the second cylindrical roller is configured to clean the second side of the substrate and the third cylindrical roller is configured to clean the first side of the substrate.

2. The brush cleaning system of claim 1, further comprising a first support roller for supporting the substrate in the first cleaning position and a second support roller for supporting the substrate in the second cleaning position.

3. The brush cleaning system of claim 1, wherein the first cylindrical roller is configured to rotate in a clockwise direction and the second cylindrical roller is configured to rotate in a counterclockwise direction when the substrate is in the first cleaning position.

4. The brush cleaning system of claim 1, wherein the second cylindrical roller is configured to rotate in a clockwise direction and the third cylindrical roller is configured to rotate in a counterclockwise direction when the substrate is in the second cleaning position.

5. The brush cleaning system of claim 1, further comprising a first sprayer configured to direct a cleaning fluid toward the first side of the substrate and a second sprayer configured to direct the cleaning fluid toward the second side of the substrate when the substrate is in the first cleaning position.

6. The brush cleaning system of claim 5, further comprising a third sprayer, and when the substrate is in the second cleaning position, the third sprayer is configured to direct a cleaning fluid toward the first side of the substrate and a second sprayer is configured to direct the cleaning fluid toward the second side of the substrate.

7. The brush cleaning system of claim 6, wherein the first sprayer directs cleaning fluid toward the first cylindrical roller when the substrate is in the second cleaning position.

8. The brush cleaning system of claim 6, wherein the third sprayer directs cleaning fluid toward the third cylindrical roller when the substrate is in the first cleaning position.

9. The brush cleaning system of claim 6, wherein each of the first, second, and third sprayers includes at least two nozzles.

10. The brush cleaning system of claim 1, wherein at least one of the first cylindrical roller and the third cylindrical roller are positioned at an angle from 3° to 15° relative to the substrate.

11. A method of cleaning a substrate, comprising:
positioning the substrate at a first cleaning position between a first cleaning roller and a second cleaning roller in a brush cleaner;
cleaning a first side of the substrate using the first cleaning roller and cleaning a second side of the substrate using the second cleaning roller;
positioning the substrate at a second cleaning position between the second cleaning roller and a third cleaning roller in the brush cleaning; and
cleaning the first side of the substrate using the third cleaning roller and cleaning the second side of the substrate using the second cleaning roller.

12. The method of claim 11, further comprising supporting the substrate in the first cleaning position using a first support roller and supporting the substrate in the second cleaning position using a second support roller.

13. The method of claim 11, wherein when the substrate is in the first cleaning position, cleaning the first side comprises rotating the first cleaning roller in a clockwise direction, and cleaning the second side comprises rotating the second cleaning roller in a counterclockwise direction.

14. The method of claim 11, wherein when the substrate is in the second cleaning position, cleaning the first side comprises rotating the third cleaning roller in a counterclockwise direction, and cleaning the second side comprises rotating the second cleaning roller in a clockwise direction.

15. The method of claim 11, wherein when the substrate is in the first cleaning position, the method further comprises directing a cleaning fluid toward the first side of the substrate using a first sprayer and directing the cleaning fluid toward the second side of the substrate using a second sprayer.

16. The method of claim 15, wherein when the substrate is in the second cleaning position, the method further comprises directing the cleaning fluid toward the first side of the substrate using a third sprayer and directing the cleaning fluid toward the second side of the substrate using the second sprayer.

17. The method of claim 16, when the substrate is in the first cleaning position, the method further comprises directing the cleaning fluid toward the third cleaning roller using the third sprayer.

18. The method of claim 16, when the substrate is in the second cleaning position, the method further comprises directing the cleaning fluid toward the first cleaning roller using the first sprayer.

19. The method of claim 11, wherein positioning the substrate at the second cleaning position comprises moving the substrate from the first cleaning position to the second cleaning position and rotating the substrate such that the second side of the substrate faces the second cleaning roller when the substrate is in either the first cleaning position or the second cleaning position.

20. The method of claim 11, wherein the first cleaning roller and the second cleaning roller are positioned at an angle from 0° to 15° relative to the substrate.
